(19) United States
(12) Patent Application Publication
(10) Pub. No.: US 2024/0105557 A1
(43) Pub. Date: Mar. 28, 2024

(54) NO-LEAD INTEGRATED CIRCUIT HAVING AN ABLATED MOLD COMPOUND AND EXTRUDED CONTACTS

(71) Applicant: TEXAS INSTRUMENTS INCORPORATED, Dallas, TX (US)

(72) Inventors: Laura May Antoinette Clemente, MABALACAT CITY (PH); John Carlo Molina, LIMAY (PH)

(21) Appl. No.: 17/951,162

(22) Filed: Sep. 23, 2022

(51) Int. Cl. H01L 23/495; H01L 21/02; H01L 21/306; H01L 21/56; H01L 23/00; H01L 23/31

(52) U.S. Cl. CPC H01L 23/49503; H01L 21/02098; H01L 21/306; H01L 21/561; H01L 23/3107; H01L 23/4952; H01L 24/43; H01L 24/48; H01L 2224/48091; H01L 2224/48105; H01L 2224/48177

(57) ABSTRACT

An electronic device includes a leadframe including a die pad and contacts, where a die attached is to the die pad. Wire bonds are attached from the die to the contacts and a mold compound overlies the leadframe and encapsulates the die and the wire bonds. The mold compound has angled side surfaces that extend from a top of the mold compound to a bonding surface of the contacts. The contacts extend from the angled side surfaces in a range of approximately 100 to 300 um.

### TECHNICAL FIELD

The present disclosure relates to an electronic device and more specifically, to a no-lead integrated circuit having an ablated mold compound.

### BACKGROUND

No-lead integrated circuit (IC) packages (e.g., Quad Flat No-Lead, Small Outline No-Lead) include a leadframe, one or more dies, wire bonds, and a molding compound. No-lead IC packages can be singulated via a punched process or a sawing process. Punch type no-lead IC packages tend to be associated with lower volume production products, where sawn type no-lead IC packages tend to support a higher volume production. Sawn type no-lead IC packages, however, do not provide the same board level reliability (BLR) as a punch type no-lead IC package. On the other hand, punch type no-lead packages require dedicated single mold cavities of multiple sizes.

### SUMMARY

In described examples, a method includes providing an array of leadframes and depositing a die on a die attach pad of each leadframe of the array of leadframes. Wire bonds are attached from the die to a bonding surface of contacts of each leadframe of the array of leadframes. A mold compound is deposited over the array of leadframes, where the mold compound encapsulating each of the die and the wire bonds. The mold compound is ablated, via a laser, in a saw street aligned between adjacent contacts of adjacent leadframes and the array of leadframes are singulated to form electronic device packages.

In another described example, a method of fabricating a no-lead integrated circuit includes providing an array of leadframes and depositing a die on a die attach pad of each leadframe of the array of leadframes. Wire bonds are attached from the die to a bonding surface of contacts of each leadframe of the array of leadframes. A mold compound is deposited over the array of leadframes, where the mold compound encapsulating each of the die and the wire bonds. The mold compound is ablated, via a laser, in a saw street aligned between adjacent contacts of adjacent leadframes to form angled side surfaces of the mold compound and the array of leadframes are singulated to form the no-lead integrated circuit.

In another described example, an electronic device includes an electronic device includes a leadframe including a die pad and contacts, where a die is attached to the die pad. Wire bonds are attached from the die to the contacts and a mold compound overlies the leadframe and encapsulates the die and the wire bonds. The mold compound has angled side surfaces that extend from a top of the mold compound to a bonding surface of the contacts. The contacts extend from the angled side surfaces in a range of approximately 100 to 300 um.

### BRIEF DESCRIPTION OF THE DRAWINGS

FIG. 1 is a cross-sectional view of an example electronic device.

FIG. 2 illustrates a cross-sectional view of a substrate in the early stages of fabrication of an electronic device of FIG. 1.

FIG. 3 illustrates a cross-sectional view of the electronic device of FIG. 2 after undergoing a first etching process.

FIG. 4 illustrates a cross-sectional view of the electronic device of FIG. 3 after undergoing a second etching process.

FIG. 5 illustrates a cross-sectional view of the electronic device of FIG. 4 after being flipped or rotated 180° and having a die attach material deposited on a surface of the substrate.

FIG. 6 illustrates a cross-sectional view of the electronic device of FIG. 5 after having a die deposited on the die attach material.

FIG. 7 illustrates a cross-sectional view of the electronic device of FIG. 6 after having wire bonds attached from the die to a surface of the substrate.

FIG. 8 illustrates a cross-sectional view of the electronic device of FIG. 7 after having a mold compound formed over the substrate, the die and the wire bonds.

FIG. 9 illustrates a cross-sectional view of the electronic device of FIG. 8 after undergoing an ablation to the mold compound.

FIG. 10 illustrates a cross-sectional view of the electronic device of FIG. 9 after undergoing a singulation process.

FIG. 11 illustrates a cross-sectional view of the example electronic device.

### DETAILED DESCRIPTION

Disclosed herein is an electronic device, more specifically, an integrated circuit (IC) package and method of fabricating the IC package. The IC package is a no-lead package (e.g., quad flat no-lead (QFN), small outline no-lead (SON)) that includes a mold compound having angled side walls, similar to that of a punched QFN package. The IC package, however, is not fabricated using the punched QFN process. Rather, the method includes ablating the mold compound with a laser to create the angled side walls. Ablating the mold compound eliminates the need for dedicated single mold cavities of multiple sizes and singulation tooling used in the punched QFN process. Thus, the disclosure creates a punch-like outline on a map molded no-lead IC package by performing laser ablation on the mold compound that covers a saw street of the leadframe before performing the final singulation of the leadframe, either by laser package saw or by blade singulation.

In addition, the IC package includes extruded contacts that extend from the angled side walls of the mold compound, which is not present in a punched QFN package. The extruded contacts improve board level reliability (BLR) and are desired for certain applications to improve performance. Channels or grooves are defined on an attachment surface of the extruded contacts. The channels effectively increase a solder area of the contacts thereby further improving the BLR.

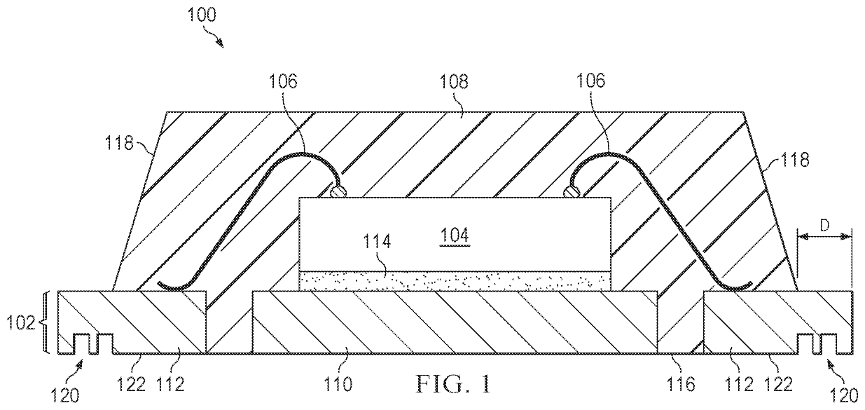

FIG. 1 is a side view of an example electronic device (e.g., integrated circuit (IC) package) 100 comprised of a leadframe 102, a die 104, wire bonds 106, and a mold compound 108. The electronic device 100 can be comprised of a no-lead IC package including, but not limited to a Quad Flat No-Lead (QFN), a Small Outline No-Lead (SON), etc.

The leadframe 102 includes a die pad (thermal pad) 110 and contacts (terminal pads) 112. The die 104 attaches to the die pad 110 via a die attach material 114. The die pad 110 may be comprised of a thermal pad that is exposed on an attachment side 116 of the electronic device 100. The thermal pad creates an efficient heat path away from the electronic device 100 to a board (e.g., printed circuit board). In addition, the exposed thermal or die pad 110 also enables a ground connection to the board.

The contacts 112 are exposed on both the attachment surface 116 and on each side of the electronic device 100. In addition, the contacts extend or are extruded from each side wall 118 of the mold compound 108 by a distance D that ranges from 100 to 300 um depending on the size of the IC package 100 thereby forming extruded contacts. Channels or grooves 120 are defined in an attachment surface 122 of each contact 112. As mentioned above, the channels effectively increase the solder area of the contacts 112 thereby further improving the BLR.

The mold compound 108 covers all but one surface of the leadframe 102, with the exception of the portion of the contacts 112 that extrudes from the mold compound 108, where the one surface not covered faces away from the electronic device 100. The mold compound 108 also encapsulates the die 104 and the wire bonds 106. The mold compound has angled side walls 118 that are formed via a laser ablation process described below. Thus, the electronic device 100 has the same configuration as a punched no-lead IC package, but is fabricated via a different fabrication process described below.

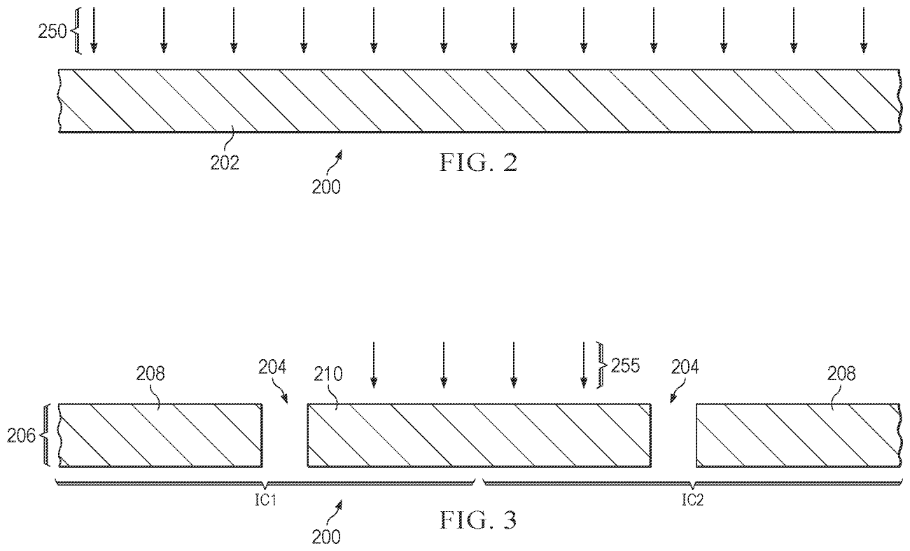

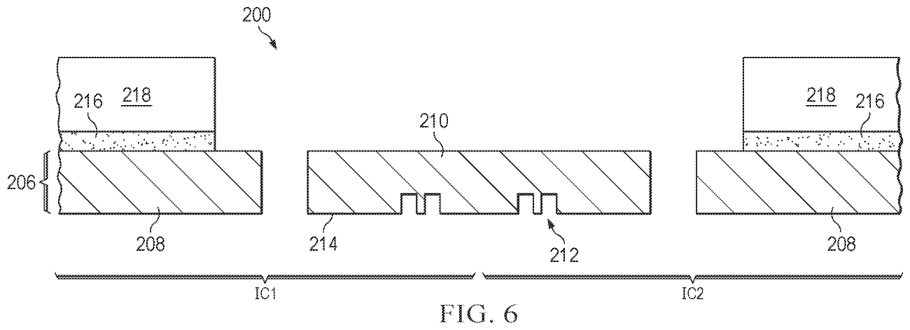

FIGS. 2-11 illustrate a fabrication process 200 associated with the formation of the no-lead electronic device 100 illustrated in FIG. 1. Though depicted sequentially as a matter of convenience, at least some of the actions shown can be performed in a different order and/or performed in parallel. Alternatively, some implementations may perform only some of the actions shown. Still further, although the example illustrated in FIGS. 2-11 is an example method illustrating the example configuration of FIG. 1, other methods and configurations are possible. It is understood that although the method illustrated in FIGS. 2-11 depicts the fabrication process of adjacent IC packages to illustrate the mold compound ablation process, the process applies to an array of IC packages. Thus, after fabrication of the array of IC packages the mold compound is ablated and the array is singulated to separate the IC packages from the array.

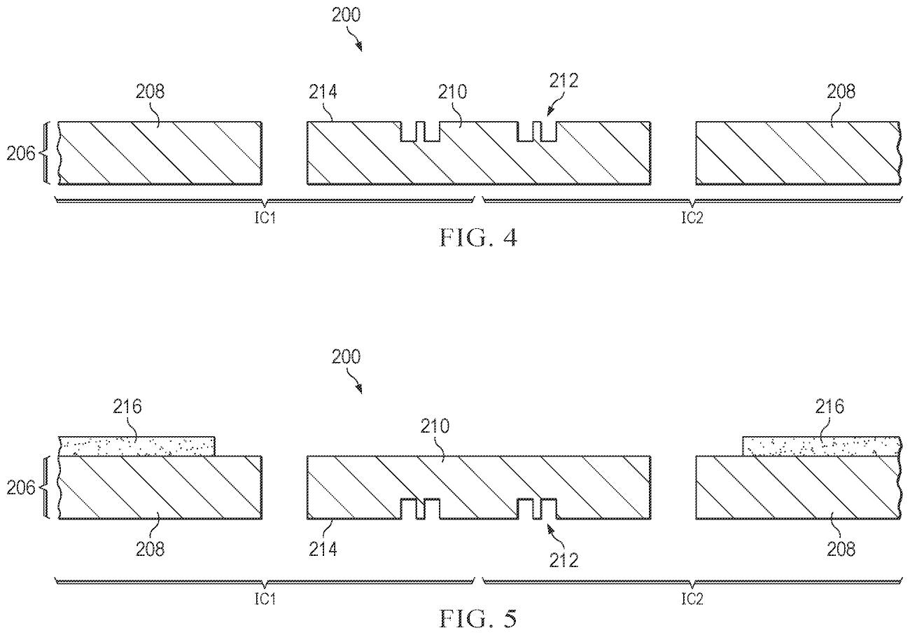

Referring to FIG. 2, the fabricating process 200 begins with a substrate comprised of a metal (e.g., copper) layer 202. The metal layer 202 is etched via a first etching process 250 to form openings 204 thereby forming a leadframe 206 resulting in the configuration of FIG. 3. The configuration in FIG. 3 illustrates a portion of adjacent IC packages (e.g., a first IC package IC1 and a second IC package IC2) in an initial fabrication stage. The leadframe 206 of each IC package IC1, IC2 includes a die pad 208 and contacts (terminal pad) 210. The configuration in FIG. 3 undergoes a second etching process 255 to form channels or grooves 212 in an attachment surface 214 of the leadframe 206 resulting in the configuration in FIG. 4. The leadframe 206 is flipped 180° so that processing can continue on a side opposite the attachment surface 214. In addition, a die attach material 216 is deposited on a surface of the die pad 208 resulting in the configuration in FIG. 5.

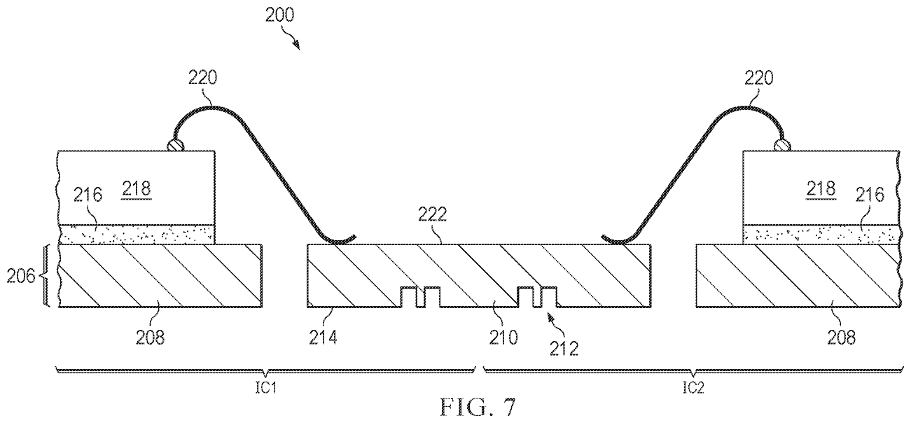

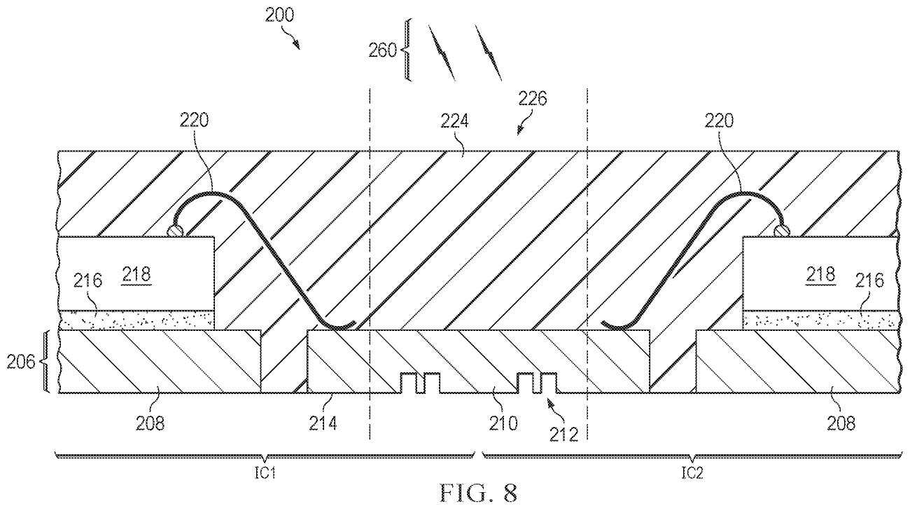

A die 218 is deposited on the die attach material 216 on the die pad 208 for each IC package IC1, IC2. Wire bonds 220 are attached to a surface of the die 218 and to a surface 222 of the contacts 210 opposite that of the attachment surface 214 of the leadframe 206 resulting in the configuration in FIG. 7. A mold compound 224 is formed over the leadframe 206 and covers all but the attachment surface 214 of the leadframe 206 resulting in the configuration in FIG. 8. The mold compound 224 encapsulates the die 218 and the wire bonds 220.

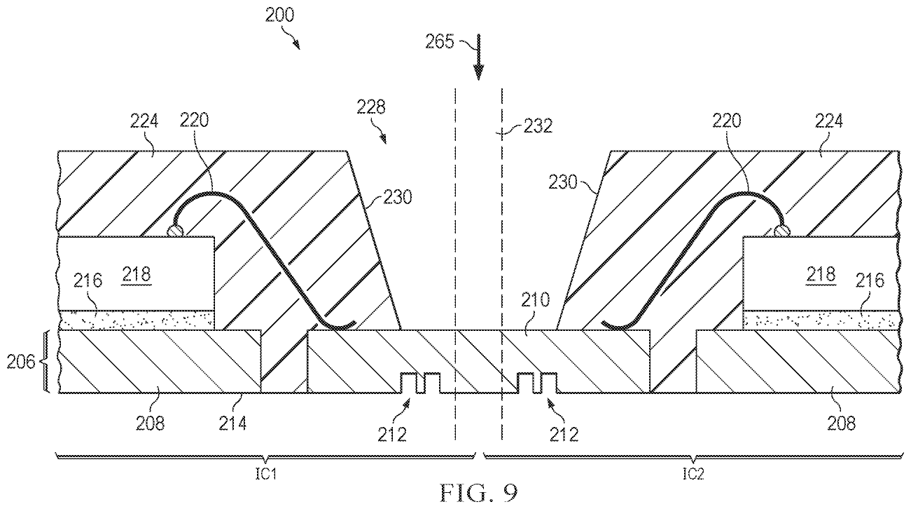

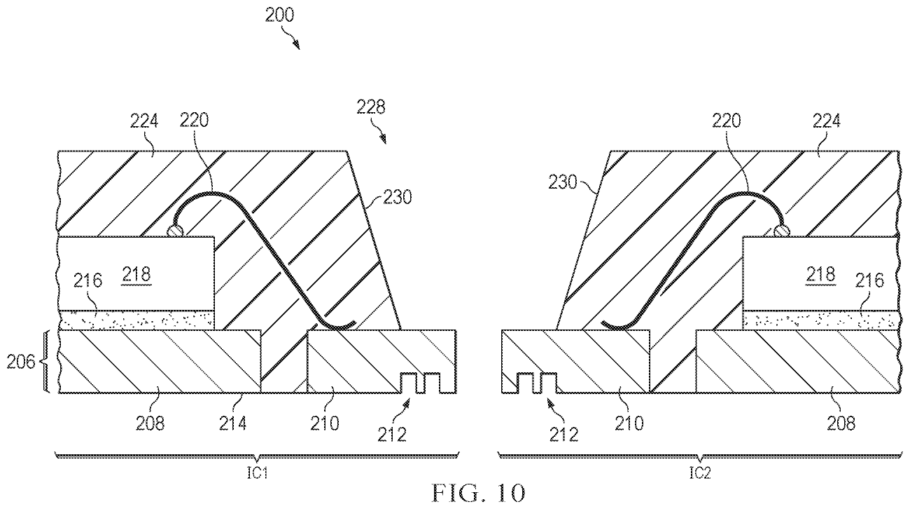

The configuration in FIG. 8 undergoes an ablation process 260 to remove a portion of the mold compound 224 in an ablation pathway 226 thereby forming a gap 228 between adjacent IC packages IC1, IC2 resulting in the configuration in FIG. 9. The ablation process 260 is performed by a laser that removes the mold compound 224 in such a manner to form angled side walls 230 of the mold compound 224. Parameters (e.g., frequency, current, pulse duration (time), number of laser passes, etc.) for the laser are based on a thickness of the mold compound 224 to be ablated. For example, the thickness of the mold compound 224 can range from 0.55 mm to 1.50 mm. Thus, in this example, an amount of mold compound 224 that the laser will ablate is in the range of 0.55 mm to 1.50 mm. Therefore, for a mold compound having a thickness in the range of 0.55 mm to 1.50 mm, the frequency can range from 15 kHz to 25 kHz, the current can range from 25 A to 30 A, the laser pulse duration can range from 100 ns to 200 ns, and the number of passes can range from 1-5.

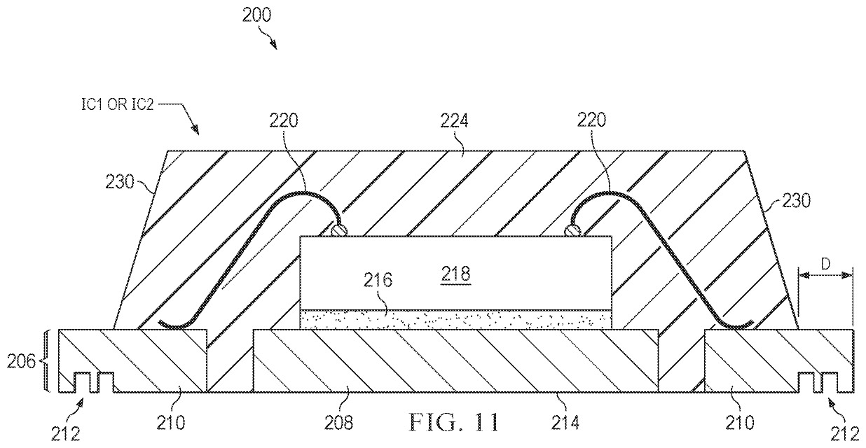

The configuration in FIG. 9 undergoes a singulation process 265 to separate the IC packages IC1, IC2 from each other resulting in the configuration of FIG. 10. The singulation process 265 is performed in a saw street 232 by either blade singulation, saw singulation, or laser singulation. FIG. 11 illustrates a final IC package IC1 or IC2 after the singulation process 265. As mentioned above, the contacts 210 extend or are extruded from each angled side wall 230 of the mold compound 224 by a distance D that ranges from 100 to 300 um thereby forming extruded contacts.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. A method comprising:
providing an array of leadframes;
depositing a die on a die attach pad of each leadframe of the array of leadframes;
attaching wire bonds from the die to a bonding surface of contacts of each leadframe of the array of leadframes;
depositing a mold compound overlying the array of leadframes, the mold compound encapsulating each of the die and the wire bonds;
ablating, via a laser, the mold compound in an ablation pathway aligned between adjacent contacts of adjacent leadframes; and
singulating the array of leadframes to form electronic device packages.

2. The method of claim 1, wherein prior to depositing a die on the die attach pad of each leadframe of the array of leadframes, the method further comprising performing a first etching process to form the die attach pad and the contacts in each leadframe of the array of leadframes.

3. The method of claim 2 further comprising performing a second etching process to form channels in an attachment surface of each of the contacts.

4. The method of claim 1, wherein ablating the mold compound forms an angled side surface of the mold compound, the angled side surface extending from a first surface of the mold compound to the bonding surface of each of the contacts.

5. The method of claim 4, wherein ablating the mold compound to form the angled side surface forms an extruded contact, where the extruded contact extends from the angled side surface of the mold compound in a range of approximately 100 to 300 um.

6. The method of claim 1, wherein ablating, via a laser, the mold compound in an ablation pathway aligned between adjacent contacts of adjacent leadframes includes setting a frequency of the laser to approximately 25-35 kHz and a current to approximately 25-30 A.

7. The method of claim 6, wherein the laser ablates the mold compound for a duration of approximately 100-200 ns.

8. The method of claim 7, wherein the laser ablates the mold compound to a depth of approximately 0.55-1.50 mm.

9. A method of fabricating a no-lead integrated circuit comprising:
providing an array of leadframes;
depositing a die on a die attach pad of each leadframe of the array of leadframes;
attaching wire bonds from the die to a bonding surface of contacts of each leadframe of the array of leadframes;
depositing a mold compound overlying the array of leadframes, the mold compound encapsulating each of the die and the wire bonds;
ablating, via a laser, the mold compound in an ablation pathway aligned between adjacent contacts of adjacent leadframes to form angled side surfaces of the mold compound; and
singulating the array of leadframes to form the no-lead integrated circuit.

10. The method of fabricating the no-lead integrated circuit of claim 9, wherein prior to depositing a die on the die attach pad of each leadframe of the array of leadframes, the method further comprising performing a first etching process to form the die attach pad and the contacts in each leadframe of the array of leadframes.

11. The method of fabricating the no-lead integrated circuit of claim 10 further comprising performing a second etching process to form channels in an attachment surface of each of the contacts.

12. The method of fabricating the no-lead integrated circuit of claim 9, wherein the angled side surfaces extend from a first surface of the mold compound to a bonding surface of each of the contacts.

13. The method of fabricating the no-lead integrated circuit of claim 12, wherein ablating the mold compound to form the angled side surfaces forms an extruded contact, where the extruded contact extends from the angled side surfaces of the mold compound in a range of approximately 100 to 300 um.

14. The method of fabricating a no-lead integrated circuit of claim 13, wherein the no-lead integrated circuit is a quad flat no-lead integrated circuit or a small outline no-lead integrated circuit.

15. The method of fabricating the no-lead integrated circuit of claim 9, wherein ablating, via a laser, the mold compound in an ablation pathway aligned between adjacent contacts of adjacent leadframes includes setting a frequency of the laser to approximately 25-35 kHz and a current to approximately 25-30 A.

16. The method of fabricating the flat no-lead integrated circuit of claim 15, wherein the laser ablates the mold compound for a duration of approximately 100-200 ns.

17. The method of fabricating the no-lead integrated circuit of claim 16, wherein the laser ablates the mold compound to a depth of approximately 0.55-1.50 mm.

18. An electronic device comprising:
a leadframe including a die pad and contacts;
a die attached to the die pad;
wire bonds attached from the die to the contacts; and
a mold compound overlying the leadframe and encapsulating the die and wire bonds, the mold compound having angled side surfaces that extend from a top of the mold compound to a bonding surface of the contacts,
wherein the contacts extend from the angled side surfaces in a range of approximately 100 to 300 um.

19. The electronic device of claim 18, wherein at least one channel is defined in an attachment surface of the contacts.

20. The electronic device of claim 18, wherein the electronic device is a quad flat no-lead integrated circuit or a small outline no-lead integrated circuit.
